(19) United States
(12) Patent Application Publication
(10) Pub. No.: US 2026/0293373 A1
(43) Pub. Date: Sep. 24, 2026

(54) OPTOELECTRONIC DEVICE AND METHOD FOR PROCESSING THE SAME

(71) Applicant: ams-OSRAM International GmbH, Regensburg (DE)

(72) Inventors: Martin Hetzl, Painten (DE); Norwin von Malm, Thumhausen/Nittendorf (DE); Philipp Kreuter, Regensburg (DE); Tansen Varghese, Regensburg (DE)

(21) Appl. No.: 19/469,207

(22) PCT Filed: Mar. 18, 2024
(86) PCT No.: PCT/EP2024/057198

§ 371 Date: Sep. 25, 2025

(30) Foreign Application Priority Data
Mar. 30, 2023 (DE) 10 2023 108 246.9

(51) Int. Cl. H10H 20/815; H10H 20/01; H10H 20/812; H10H 20/824; H10H 20/84

(52) U.S. Cl. CPC H10H 20/815; H10H 20/0133; H10H 20/034; H10H 20/824; H10H 20/84; H10H 20/812

(57) ABSTRACT

In an embodiment an optoelectronic device includes a semiconductor layer stack including a first doped layer having a first doping type, a second doped layer having a second doping type and an active layer between the first doped layer and the second doped layer, wherein a material of the semiconductor layer stack comprises AlGaAs and/or GaAs, wherein the semiconductor layer stack comprises mesa sidewalls extending from the first doped layer to the second doped layer, and a functional structure arranged on a surface of the sidewalls at least at the active layer, the functional layer structure configured to cause a reduction of a radiative recombination lifetime, wherein the functional structure comprises a dielectric oxide containing layer disposed on the sidewalls of the semiconductor layer stack and optionally extending partially onto a top surface of the semiconductor layer stack.

### CROSS-REFERENCE TO RELATED APPLICATIONS

This patent application is a national phase filing under section 371 of PCT/EP2024/057198, filed Mar. 18, 2024, which claims the priority of German patent application no. 10 2023 108 246.9, filed Mar. 30, 2023, each of which is incorporated herein by reference in its entirety.

### TECHNICAL FIELD

The present invention concerns an optoelectronic device, in particular a μLED for data communication and a method of processing the same.

### BACKGROUND

The use of μLEDs for optical and data communication has several benefits. Apart from the small size, which provides an easier interconnect to fibre optics, the vertical optoelectronic components provide an improved scalability and can be easily implemented in existing designs at large numbers. In this regard a μLED is an optoelectronic component that comprises a diameter or more general a dimension that is smaller than 50 μm and in particular smaller than 20 μm. In some special applications, a μLED can range in diameter between 2 μm and 10 μm.

μLEDs in comparison to conventional LEDs with larger sizes further require a very low current resulting in an overall low power consumption, thereby reducing the amount of heat generated during operation. This again not only saves power, which is particularly suitable for short and midrange interconnects, but also simplifies the requirements regarding the heat transfer layer enabling a dense application of such optoelectronic components. However, apart from the requirement of a high quantum efficiency to provide enough light, data communication also requires a high switchability or more general a large amplitude modulation depth at high frequencies. Current optical data communication ranges from several hundred Megahertz to a few Gigahertz, for example in the range between 10 GHz and 50 GHz.

As a result thereof, current μLEDs have to be switched on and off or at least modulated in their respective emission amplitude within that frequency range. Given the fact, that a light pulse in itself requires a certain length to be detected at the receiver end, such high frequencies require a radiative recombination lifetime in the range of a few ten picoseconds and less. The radiative recombination lifetime is the time required for the minority charge carriers to recombine under radiation after turning off the current through the μLEDs. Consequently, the radiative recombination life directly affects the fall time of a light pulse emitted by the μLEDs.

Various measures have been proposed to reduce the rise and fall times during a pulse or amplitude modulated emission, as current μLEDs are limited in this regard resulting in a switching time of only a few hundred megahertz and rise and fall times to 100 ps or more.

As an example, background doping in the quantum barriers of the respective optoelectronic components can be implemented in order to increase the charge carrier density. While this is suitable in some cases, it requires a precise control during the epitaxial growth of the quantum barriers. As an alternative, non-radiative defect centres within the active region can be provided to increase the non-radiative recombination competing with radiative recombination of the charge carrier. However, due to dopant or defect centre diffusion and other characteristics, those induced measures face reliability issues and are difficult to control during processing of the devices.

### SUMMARY

Embodiments provide optoelectronic devices or optoelectronic components having a reduced carrier lifetime in order to provide the highest switchability during modulation.

Embodiments provide that for optoelectronic devices based on a gallium arsenide, GaAs or aluminum gallium arsenide AlGaAs material systems, non-radiative recombination centres can be introduced into the semiconductor layer stack in a controlled way. More particularly, rather than including those non-radiative recombination centres in the active layer as in conventional techniques, the density of such non-radiative recombination centres is adjusted at the mesa facets of the respective semiconductor layer stack of the optoelectronic device to obtain the required fall-time. The density of such non-radiative recombination centres can be chosen to depend on the overall size of the active region and other measures already known in the art. As a result thereof, the lifetime for the radiative recombination and subsequently the fall-time is reduced.

In this regard, the radiative recombination rate is substantially proportional to the product of the charge carrier concentrations in the active layer. Therefore, a high concentration of charge carriers in the active region decreases the radiative recombination time and the probability of the non-radiative recombination. This effect can be further enhanced by using quantum well structures and multi-quantum well structures, thus confining the charge carriers to a small region due to the bandgap structure.

However on the other hand, an increase in the non-radiative recombination rate competes with the radiative recombination rate. It has been found that such non radiative recombination centres at the mesa facets can further reduce radiative recombination time without a large trade-off with the quantum efficiency. Hence, a controlled increase of the non-radiative recombination rate can be used in accordance with the proposed principle to decrease the radiative recombination time and subsequently the fall-time of light pulses emitted by the respective optoelectronic device. In particular, the fall-time of light pulses can be accelerated to a few 10 picoseconds and even less.

In an aspect of the proposed principle, an optoelectronic device comprises a semiconductor layer stack. The semiconductor layer stack includes a first doped layer having a first doping type and a second doped layer having a second doping type. The first doping type can for example include an n-type doping, while the second doping type may include a respective p-type doping. In this regard, the first and second doped layer may comprise a plurality of sub-layers including different doping concentrations and doping profiles, respectively. For example, doped sub-layers opposite an active layer or region may comprise a higher doping concentration suitable for current distribution across the overall area of the respective doped layer.

An active layer is arranged between the first and second doped layer. In some aspects, the second doped layer may comprise a simple pn-junction. In some other aspects, the active layer may comprise a quantum well layer. As a further alternative, the active layer may include a multi-quantum well structure having a plurality of alternating barrier layers and quantum well layers, respectively.

In accordance with the proposed principle, the material for the semiconductor layer stack comprises gallium arsenide, GaAs or aluminum gallium arsenide AlGaAs. Said combination of materials is suitable to emit light in the red, and infrared portion of the spectra. In this regard, the aluminum content of the aluminum gallium arsenide AlₓGa₁₋ₓAs layers within the layer stack may vary with parameter x and can be in the range between 0% and 70%, respectively. In some aspects, the Al content varies depending on the colour and can reach up to 80% in the outer layers with decreasing Al content in the direction of the active layer. with longer wavelengths, i.e. in the infrared spectrum, the Al content can be 30 % and less. In some aspects, the active layer may comprise no Al content or less than 10% in some further aspects, the active layer may comprise InGaAs with an In content from 0% to 50%. In this regard an active layer may comprise a multi-quantum well with its barrier layers having an Al content of larger than 10% and its quantum well layers having an Al content of less than 10%.

The semiconductor layer stack comprises mesa etched sidewalls, extending from the first doped layer to the second doped layer. the mesa-etches sidewalls also referred to a mesa facets. The mesa etched sidewalls can be inclined with a varying degree of inclination. In some aspects, the mesa facets extend along a certain crystal direction, in particular in a direction that generates only a few natural non-radiative recombination centres. In some aspects, the inclination of the sidewalls can change. In particular, the inclination of the sidewalls close to the active region may be smaller than an inclination further away and particularly on one of the first and second doped layer, respectively.

In accordance with the proposed principle, a functional structure is arranged and deposited on the surface of the mesa etched sidewalls at least at the region of the active layer. The functional structure is configured to cause a reduction of the radiative recombination lifetime.

For example, this is achieved by inducing a controlled density of non-radiative recombination centres at the sidewalls and the parameter of the active layer. The functional structure can be attached on the surface that is on the mesa facet of the active layer but can also form an integral part of the surface itself.

By using a controlled process to induce non-radiative recombination centres, the density of such centres at the mesa facet of the semiconductor layer stack is controllable and adjusted to change the carrier lifetime to the desired needs. Hence, a trade-off between efficiency and the on/off switching for the modulation speed in accordance with the application requirements is achieved.

Several aspects relate to the controlled defect formation and the functional structure arranged on the surface and mesa facets of the active layer. In some aspects, the functional structure comprises one of carbon, nitrogen and oxygen atoms or molecules that terminate the dangling bonds of the surface. In some aspects, the functional structure is configured to cause a band bending of the active layer close to the surface or mesa facets. The non-radiative recombination centres are located within the bandgap.

In some aspects, the functional structure comprises a surface, which is roughened by a controlled plasma etching process. It is noted that the controlled plasma etching process is different from a process for cleaning the mesa facets and sidewalls of the semiconductor layer stack after the mesa etching process itself. While the purpose of the latter is actually to reduce the density of non-radiative recombination centres and anneal the mesa facets and sidewalls, the surface roughening by the controlled plasma etching process deliberately induces surface states with a non-radiative recombination characteristics. It has been found that the mesa etching results in a kind of unpredictable density of states and therefore a cleaning and annealing process might be suitable. In this regard, damages caused by the mesa etching step on the sidewalls can be cleaned and removed in some aspects using NH3 or NH4OH. This will clean the sidewalls providing a defined base for the subsequent application of the functional structure.

The plasma damage induced by the etching process can be controlled by the concentration of the plasma used for the process, the temperature as well as the plasma content and time duration for the process. In some aspects, a material for the process can be used, which is more selective to the material of the active layer than to other layers. In some aspect, the plasma etching process includes the incorporation of carbon, nitrogen or oxygen onto the surface of the layer stack.

As an alternative embodiment for the functional structure, an oxidation layer is deposited on the surface of the mesa etched sidewalls and the mesa facets at least at the active layer. However, similar to the other embodiments for the functional structure, the oxidation layer may also extend across the first and second doped layers. The oxidation layer can be generated by either depositing an oxidized material directly on the surface or by an active oxidation of the surface of the semiconductor stack itself using an oxygen containing material.

Similar to the previous embodiment, the level of oxidation as well as the depth into the active layer is controlled and results in a defined density and distribution of non-radiative recombination centres.

As a further alternative for the functional structure, a dielectric material, for example, comprising oxygen or an oxidized material can be deposited on the surface of the mesa etched sidewalls and the mesa facets, respectively. Such layer may terminate the dangling bonds of the surface forming defined interface states, which cause non-radiative recombination. In another alternative, a layer is deposited containing one of nitrogen, oxygen and carbon. In this regard, the layer can be deposited and subsequently oxidized for example, in an oven or the like.

In some aspects, the functional structure comprises a functional layer on the mesa facets and the surface of the mesa etched sidewalls at least at the active layer. The functional layer is covered by an epitaxially regrown encapsulation layer disposed directly on the functional layer. The encapsulation layer can extend along the sidewalls of the semiconductor layer stack thereby covering the functional layer completely as well as partially onto the top surface of the semiconductor layer stack. The regrown encapsulation layer can comprise a nitride or an oxide, for example, an Al2O3 layer and or AlN layer. The respective encapsulation layer can be processed by regrowth but also synthesized by reactive ion plasma sputtering process or any other suitable means.

However, if the encapsulation layer is not transparent, an additional recess is provided on the top surface to provide access for an electrical contact of the device. In some aspects, the functional structure can further comprise a reflective material.

In some aspects, the functional structure comprises a dielectric oxide containing layer. The dielectric oxide containing layer is disposed on the sidewalls of the semiconductor layer stack for example by a respective regrowth or sputtering process. The dielectric oxide containing layer extends partially onto the top surface of the semiconductor layer stack. In some aspects, the dielectric oxide containing layer can comprise one of SiO2, Nb2O5, HfO2 or SiOH for example. In some other aspects, the functional structure comprises a dielectric nitride containing layer. This layer may include SiN for example.

The deposition of the dielectric material forms charged interface states, which provide static non-radiative recombination centres. These are formed on the sidewalls of at least at the active layer acting as traps for the charge carriers, preferably within the bandgap of the active layer material, thereby reducing the radiative recombination lifetime.

In some further aspects, the functional structure comprises a regrown and subsequently oxidized AlₓGa₁₋ₓAs layer disposed on the sidewalls of the semiconductor layer stack. Again, the oxidized AlₓGa₁₋ₓAs layer may extend partially onto the top surface of the semiconductor layer stack. The aluminum content in AlₓGa₁₋ₓAs layer prior to oxidation is chosen to be larger than 50% in regard to the Ga content (parameter x>0.50) and particularly more than 90% (parameter x>0.90) and more particularly, more than 97% (parameter x>0.97). In some aspects, the regrown layer comprises Al_{0.98}Ga_{0.02}As as material, which is 98% aluminum. Due to the very high aluminum content, the band gap of the provided layer prior and after oxidation is large enough to avoid any shortcut between the differently doped first and second layer. Furthermore, due to the oxygen being present, the aluminum is oxidized resulting in a dielectric material forming a defined concentration of the non-radiative recombination centres at the mesa facet of the active layer.

Some further aspects concern the semiconductor layer stack. In some aspects, the semiconductor layer stack comprises a first and second,—in particular—undoped cladding layer. The cladding layers are located directly adjacent to the active region and may comprise, for example undoped aluminum gallium arsenide. The cladding layer is usually used to prevent an undesired diffusion of dopants from the doped first and second layers into the active region. The thickness of the cladding layer may range from a few nm to a few 10 nm.

In some aspects, the active region may comprise a quantum well layer having an additional doping level in the range between 1e16 1/cm³ to 1e18 1/cm³. The additional doping level increases the charge carrier density within the quantum well layer, thereby reducing the carrier lifetime. Accompanying it with the other measures, the overall radiative lifetime can be further reduced.

In some further aspects, the active layer comprises a multi-quantum well structure having a plurality of alternating barrier layers and quantum well layers. The barrier layers comprise a higher Al content than the adjacent quantum well layers. In this regard, at least two barrier layers can comprise a doping level in the range of 1e16 1/cm³ to 1e18 1/cm³. Similar to the previous embodiment, the charge carrier density in the barrier layers is increased, thereby reducing the radiative lifetime.

In some further aspects, the active region may comprise a plurality of quantum dots, in particular, GaAs/AlGaAs quantum dots. Inserting quantum dots instead of quantum wells in the active layer may also increase the overall switching speed due to their faster recombination. Similar to the previous embodiments, these aspects can be combined with the implementation of the non-radiative recombination centres.

In this regard, the optoelectronic device can be implemented as a vertical or horizontal optoelectronic component. A horizontal optoelectronic component comprises respective highly doped or otherwise conductive contact areas on the same side of the layer stack and preferably opposite the main emission surface of the component. A vertical optoelectronic component comprises respective highly doped or otherwise conductive contact areas on two opposing sides, wherein one of the contact areas may also include the main emission surface. The proposed principle illustrated in the various embodiments later on are not limited to vertical or horizontal optoelectronic devices but can be implemented in both.

Further aspects refer to a method of processing an optoelectronic device. The method provides a semiconductor layer stack having a first doped layer and the second doped layer. The first doped layer comprises a first doping type and a second doped layer comprises a second doping type. An active layer is arranged between the first and second doped layer. the layer stack is based on an GaAs/AlGaAs material combination.

In a further step, a mesa etching process is conducted to form inclined sidewalls exposing portions of the active layer on a circumferential perimeter. In a top view, said perimeter can have the shape of a circle, a rectangle, or a polygon like a hexagon for example. The surface of the inclined sidewalls and/or the mesa facets are cleaned and optionally annealed to provide a defined base state for the subsequent step. Then, a functional structure is generated on the surface of the cleaned mesa etched sidewalls. The functional structure is configured to cause a reduction of the radiative recombination lifetime.

In some aspects, the functional structure generated on the cleaned sidewalls is configured to cause a band bending of the band structure of the active layer close to the surface. Alternatively or in addition as well functional structure generates a plurality of non-radiative recombination centres located with their respective energy states within a band gap of the active layer. In operation, charge carriers populate these states located in the “forbidden” zone and can recombine non-radiatively.

Several approaches can be taken to generate such states close to the perimeter of the active layer, either within the material of the active layer itself close to its surface or in an interface between a functional layer and the perimeter of the active layer material. In some aspects, generating the functional structure comprises roughening the cleaned surface by a controlled plasma etching process. The parameter of the plasma etching process are adjusted as to form a defined number of dangling bonds and centres with their energy states within the band gap.

In some aspects, further atoms or molecules are added during the plasma process attaching those onto the dangling bond of the material on the sidewall thereby saturating the dangling bonds. Exemplary material contains oxygen, nitrogen, or carbon. As an alternative, an oxygen containing layer is deposited on the sidewalls, for example regrown. The material of an additional layer may terminate dangling bonds of the surface of the mesa-etched sidewalls and the mesa facets at least at the active layer.

In an alternate embodiment, generating the functional structure further comprises depositing an encapsulation layer on a functional layer, wherein the encapsulation layer extends along the sidewalls of the semiconductor layer stack and optionally partially onto a top surface of the semiconductor layer stack. The encapsulation layer can be regrown on the functional layer and/or deposited by a vapor deposition or other process.

In some further aspects, generating the functional structure comprises depositing a dielectric oxide containing layer on the sidewalls of the semiconductor layer stack and optionally extending partially onto a top surface of the semiconductor layer stack. The dielectric oxide containing layer comprises at least one of SiO2, Nb2O5, HfO2, SiN and SiON. In some other aspects, generating the functional structure comprises depositing a dielectric nitride containing layer on the sidewalls of the semiconductor layer stack optionally extending partially onto a top surface of the semiconductor layer stack. Material of such layer can comprise SiN for example. The material may cause certain interface states, which act as non-radiative recombination centres.

Some of those materials are transparent, while other can be reflective. In this regard, a reflective layer can also be deposited on the functional structure in order to reflect light emitted towards the side to the main emission surface.

As a further alternative for the functional structure, generating the functional structure comprises regrowing an AlₓGa₁₋ₓAs layer on the sidewalls of the semiconductor layer stack and optionally extending partially onto a top surface of the semiconductor layer stack, wherein parameter x>0.5 and in particular x>0.9 and in particular x>0.97. The regrown AlₓGa₁₋ₓAs layer is then oxidized and more particularly the Al is oxidized.

This particular layer can also be deposited during growth of the semiconductor layer stack to generate an aperture for the charge carrier resulting in an increase of carrier density in a central region of the active layer, while the density of the non-radiative recombination centres is increased on the perimeter. Hence, this approach combines both aspects to reduce the fall time. In some aspects, providing a layer stack comprises depositing an AlₓGa₁₋ₓAs layer arranged between the first doped layer and the active layer and/or the second doped layer and the active layer, wherein parameter x>0.5 and in particular x>0.9 and in particular x>0.97. The AlₓGa₁₋ₓAs layer comprises a thickness in the range of 5 nm to 20 nm and can optionally be doped in the same range as the first and second doped layers of the layer stack. Suitable doping concentrations are known to the skilled person.

To this extent the semiconductor layer stack comprises in some aspects a first and a second, in particularly undoped cladding layer directly adjacent to the active region. Those layers prevent diffusion of dopants but can also be used as a charge carrier blocking structure.

The optoelectronic device and μLED presented herein is suitable for a variety of applications, in which a high switching or current modulation frequency is required. In some aspects, the optoelectronic device according to the proposed principle is used in optical data communication, particularly in the short and medium range with modulation frequencies larger than 1 GHz and particularly larger than 10 GHz.

### BRIEF DESCRIPTION OF THE DRAWINGS

Further aspects and embodiments in accordance with the proposed principle will become apparent in relation to the various embodiments and examples described in detail in connection with the accompanying drawings in which

FIGS. 1A to 1C illustrate some steps of a method for processing an optoelectronic device in accordance with some aspects of the proposed principle;

FIGS. 2A and 2B show some further steps of a method for processing an optoelectronic device in accordance with some aspects of the proposed principle;

FIG. 3 illustrates an alternative method step for processing an optoelectronic device in accordance with some aspects of the proposed principle;

FIGS. 4A and 4B illustrate some steps of a further embodiment of a method step for processing an optoelectronic device in accordance with some aspects of the proposed principle;

FIGS. 5A and 5B show some steps of yet another embodiment of a method step for processing an optoelectronic device in accordance with some aspects of the proposed principle;

FIGS. 6A and 6B show some steps of yet another embodiment of a method step for processing an optoelectronic device in accordance with some aspects of the proposed principle; and

FIGS. 7A to 7C illustrate some aspects concerning further measures for reducing the charge carrier lifetime in combination with some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

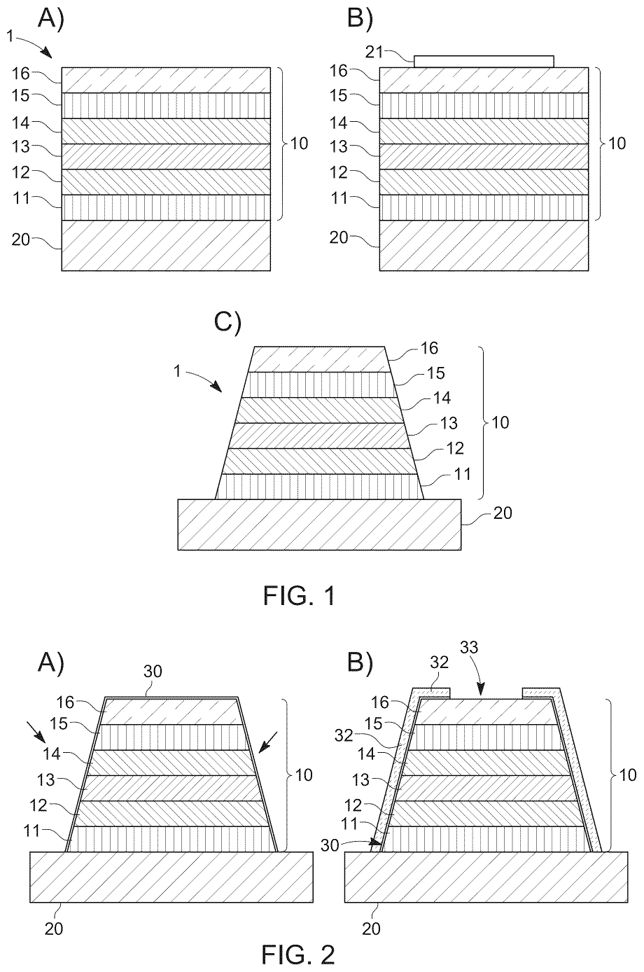

FIGS. 1A to 1C illustrate the first steps of a method for processing an optoelectronic device in accordance with the proposed principle. These steps are conducted in all the respective embodiments illustrated herein. However, certain variations and deviations from the illustrated steps can be implemented without deviating from the overall scope. In addition, although only vertical optoelectronic devices are illustrated herein, one will recognize that the proposed principle is not restricted to such devices. Rather, the respective contact areas can be arranged on the same side with a via leading through the active layer and connecting the desired doped layer.

FIG. 1A illustrates the epitaxial deposition of a semiconductor layer stack 10 on the respective growth substrate 20. The growth substrate 20 comprises an n-doped gallium arsenide layer, which acts as wafer substrate, on which the subsequent layers are epitaxially deposited. Furthermore, the n-doped gallium arsenide substrate may comprise a plurality of buffer layers to smooth and flattening its surface, such as to provide a substantially defect free surface.

In a subsequent step, an n-doped aluminum gallium arsenide layer 11 is epitaxially deposited on the surface of the growth substrate. The layer 11 can comprise a doping distribution and/or a varying doping concentration based on the required needs. For example, the doping concentration closer to the growth substrate 20 may be larger than further away to improve the charge carrier injection into the aluminum gallium arsenide layer 11. Furthermore, the aluminum content of layer 11 may vary and also comprise a respective distribution over the thickness of layer 11. To this extent, layer 11 can include one or more sublayers, in which the above-mentioned varying concentrations and distributions of dopants and Al content are implemented.

On top of layer 11, an undoped aluminum gallium arsenide cladding layer 12 is deposited. The aluminum content of that layer may be similar to the aluminum content of layer 11 directly adjacent to it but can also vary to improve the charge carrier transport diffusion into the active layer 13 epitaxially deposited on top of placing layer 12. The thickness of cladding layer 12 is in the range between 10 nm and 50 nm. The purpose of cladding layer 12 is to prevent diffusion of dopants from layer 11 into the active layer 13.

Active layer 13 is deposited thereupon and comprises a multi-quantum well structure in this embodiment. The multi-quantum well structure includes a plurality of barrier layers and quantum well layers, respectively, whereas the aluminum content for the barrier layers is slightly larger than the aluminum content of the respective quantum well layers. Consequently, a varying band gap in the semiconductor material of active layer 13 is provided, trapping the charge carriers between the “valleys” of the bandgap.

Active layer 13 is covered by another cladding layer 14 of aluminum gallium arsenide similar to the first cladding layer 12.

In some aspects, one of the cladding layers 12 and 14 may comprise a different, maybe higher Al content than the doped layer to act as an charge carrier barrier, in order to contain the charge carrier within the active layer. however, such implementation may be irrelevant if a multi-quantum well structure is used.

On top of the cladding layer 14, a p-doped layer 15 is deposited. Similar to the n-doped layer 11, the doping concentration as well as the doping distribution of the p-doped aluminum gallium arsenide layer 15 may vary.

In this regard, both layers 11 and 15 may not only comprise aluminum gallium arsenide sublayers, but can also include one or more gallium arsenide sub-layers or aluminum gallium arsenide sub-layers with varying aluminum content. The purpose of these sublayers is to distribute the injected charge carriers across the overall area of the semiconductor layer stack 10 and will provide a continuous and equally distributed diffusion towards the active region.

The top surface of layer 15 is covered by a highly doped gallium arsenide contact layer 16. The contact layer 16 provides not only a connection to a conductive metal or a transparent conductive oxide, but also acts as the main emission surface in operation of the device later on.

The next step of the proposed method is illustrated in FIG. 1B. A mask layer material is deposited on the p-doped gallium arsenide contact layer 16 and subsequently structured to form a central portion of the hard mask layer 21.

In a top view the central portion forms a circle, a rectangle, or any other polygon like a hexagon structure. Then, one or more mesa etching steps are performed to provide inclined sidewalls 17 exposing the facets of active layer 13 as well as the two doped layers 11 and 15, respectively. The results of the mesa etching process is illustrated in FIG. 2C and can be achieved by several subsequent mesa etching steps. In a twostep process, the surface of the active layer 13 is cleaned and annealed after the first etching step to remove any plasma damages from the surface of active layer 13. Then a small Al2O3 is deposited on the exposed surface areas to prevent damages from the respective surfaces. The Al2O3 layer is removed and a further yet optional cleaning process using NH3 and NH4OH, any residual material is removed from the surface of the inclined sidewalls. NH3 and NH4Oh can also be used in the first cleaning and annealing step.

For example, in a first mesa etching step, material of contact layer 16, the p-doped aluminum gallium arsenide layer 15, the cladding layers 14 and 12 as well as active layer 13 is removed using a plasma etching process or any similar suitable way. The exposed surfaces are cleaned and annealed using NH3 or other suitable gas. The cleaning reduces the damages and the non-radiative recombination centres after the mesa etching process to obtain a more defined surface, preferably with only a small number of non-radiative recombination centres and thus a defined surface state.

The surface is subsequently covered after annealing with a thin layer of Al2O3 to protect the annealed surface against the etchant of the next step. A subsequent etching process is then conducted to remove material from the n-doped layer 11, resulting in the same inclination or in a different inclination depending on the desired layer stack structure.

The existing Al2O3 layer for protecting the side walls and mesa facets of the active layer 13 is then removed and the sidewalls prepared to provide defined state of the mesa facets. This can be achieved for example by the above-mentioned cleaning processes and any other suitable means.

The resulting structure depicted in FIG. 1C) provides the basic state for the subsequent processes to induce a defined amount and concentration of non-radiative recombination centres.

The processing of a functional structure as shown in the following embodiments, can cause a variety of different states, resulting in an increased non radiative recombination ratio at the perimeter. In some aspects, simple defects are introduced. In other aspects, the functional structure causes a band bending of the active layer close to the perimeter with the energetic states of the non-radiative recombination centres being located within the bandgap. The latter can also be implemented without a significant band bending.

FIGS. 2A) and 2B) illustrate a possible embodiment thereof. For this purpose, a functional layer 30 is generated on the sidewalls of the layer stack 10 as well as the top surface of the p-doped gallium arsenide contact. For example, a controlled plasma etching process is conducted to induce a defined level of equally distributed damages across the surface of the inclined sidewalls. The damage results in dangling a bonds and other defects causing non-radiative recombination at those locations and along the perimeter of the mesa facet of layer 13. During such process nitrogen, oxygen or carbon is added to saturate the dangling bonds. By changing and adjusting the duration of the etching process as well as the concentration of the plasma one can control the thickness of the surface structure 30, which can range from a few nanometres to approximately 30 nm.

As an alternative an oxidation layer can be deposited on the surface acting as the functional structure 30. In this regard, the functional structure 30 can also be implemented by oxidizing the surface of the mesa facets of layer stack 10.

The layer stack 10 is then encapsulated to protect the functional structure 13 via an epitaxially regrowth layer depositing a dielectric material on the functional layer as well as on the top surface of layer stack 10. The dielectric material is regrown with a thickness of several 10 nm to several hundred nm. In some aspects, the dielectric material can be further covered by a reflective material to prevent a side emission.

The dielectric material at the top surface is then at least partially removed together with the functional structure 13 to provide a recess 33 and an opening therein. The recess 33 and opening acts as the main emission surface for the optoelectronic device. The material of the encapsulation layer 31 can be removed from the top surface completely or only partially as indicated in FIG. 2. In addition, and not shown herein, a transparent conductive material is deposited on the top surface for contacting the contact layer 16. The optoelectronic device can then be processed further depending on the desired application.

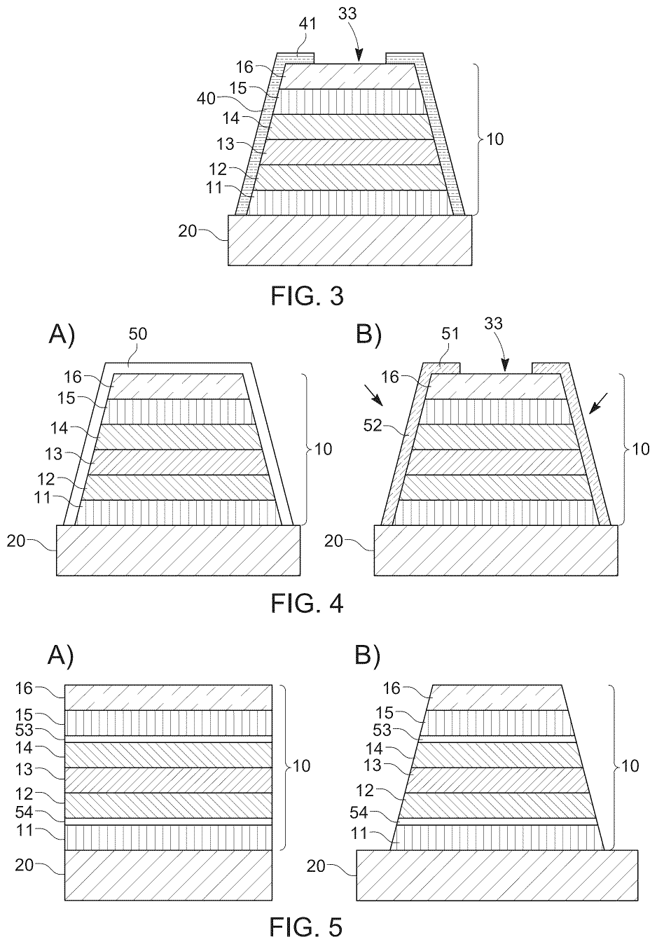

FIG. 3 illustrates an alternative embodiment after processing the layer stack providing the cleaned mesa etched sidewalls. In this embodiment, a dielectric layer 40 is deposited on the inclined sidewalls as well as partially on the surface to form a plurality of charged interface states. These interface states act as stationary a non-radiative recombination centres at which the charge carriers recombine non-radiatively during operation of the device reducing the overall radiation recombination time. For this purpose, the dielectric material 40 is deposited using for instance a sputtering process or-when implementing μLEDs-a chemical vapor deposition, gas phase deposition or physical vapor deposition process. For example, two or more precursors can be added into the reactor chamber causing a chemical reaction of the respective components on the sidewalls forming the dielectric material.

Typical materials suitable for such dielectric material on the inclined surface contain SiO2, Nb2O5, HfO2 and SIN or SION. Consequently, the required precursors require an oxygen donor. The overall thickness of the dielectric layer 40 and 41 can be is small in the range of a few of 10 nm up to a couple of hundred nanometres. The concentration of charged interface states depends on the amount and concentration during the deposition process and the deposition parameters. In addition, and not illustrated in the embodiment of FIG. 3, mask is disposed on the top surface and the dielectric material on the top surface partially removed to form recess 33 as main emission surface. Furthermore, another a dielectric layer can be disposed on the dielectric material for further protection.

In some aspects, the dielectric material is at least partially reflective for light being emitted by the active layer, such that the dielectric material can also act as a reflective barrier.

In a further aspect, the mesa etched structure can be covered by another aluminum gallium arsenide containing layer, which is subsequently processed. FIGS. 4A and 4B illustrate a respective embodiment thereof.

In accordance with the proposed principle, an aluminum containing aluminum gallium arsenide layer is epitaxially regrown on the inclined sidewalls and the top surface of layer stack 10 as indicated in FIG. 4A). The aluminum content in layer 50 (AlₓGa₁₋ₓAs) is rather high with parameter x above 0.9. The high aluminum content results in a larger bandgap which is usually large enough to prevent a residual current between the two doped layers 11 and 15 along the mesa facets. Hence, the aluminum content should be larger than 50% to avoid such short circuit. In addition, the aluminum gallium arsenide layer 50 should be as thin as possible to increase the lateral resistance between the doped layers 11 and 15. In some aspects, the aluminum content can be 100% resulting in aluminum arsenide layer, AlAs being disposed.

In a subsequent step illustrated in FIG. 4B, the disposed layer is now oxidized for example by heating the structure, while exposing the surface of layer 50 to an oxygen containing atmosphere. During this process, the aluminum is oxidized resulting in a controllable and defined density of non-radiative recombination centres on or close to the perimeter of the active layer 13. After the oxidation process is completed, another structured mask layer can be deposited on top of the contact layer 16 to form the recess 33. Similar to the previous embodiments, further protection layers can be applied on the oxidized surface of layer 52.

The deposition of an aluminum gallium arsenide layer as indicated in FIG. 4 has the benefit that the overall material system does not need to be changed, but the respective aluminum content varied. Consequently, the optoelectronic device can be a processed completely within the epitaxial deposition chamber, until the aluminum gallium arsenide layer 50 is deposited and then moved to the oxygen containing atmosphere.

In some further aspects, the charge carrier density can be increased within the active layer, thereby using proposed principle in combination with a current constraining layer. FIGS. 5A to 5B illustrate a respective process for preparing such optoelectronic device.

In some first steps, an epitaxial layer stack 10 is deposited on a growth substrate 20 similar to the previous embodiments. However, in contrast to some conventional techniques, very thin layers 53 and 54 containing aluminum gallium arsenide with a high aluminum content are introduced between the doped layer 11 and the respective cladding layer 12 or more generally between the doped layer 11 and the active layer 13. The aluminum content of the AlₓGa₁₋ₓAs layers 53 and 55 comprise a very high aluminum content with parameter x larger than 0.9 and particularly larger than 0.97 corresponding substantially to the aluminum content of the AlₓGa₁₋ₓAs layer 50 subsequently deposited on the inclined sidewalls of the layer stack.

In a subsequent step illustrated in FIG. 5B, a mesa etching process is performed to expose the respective sidewalls and mesa facets of layers 53 and 54 as well as layer 13. The sidewalls are subsequently cleaned using conventional techniques to provide a defined surface state at the inclined sidewalls. These steps are similar to the ones previously described and varied according to the needs.

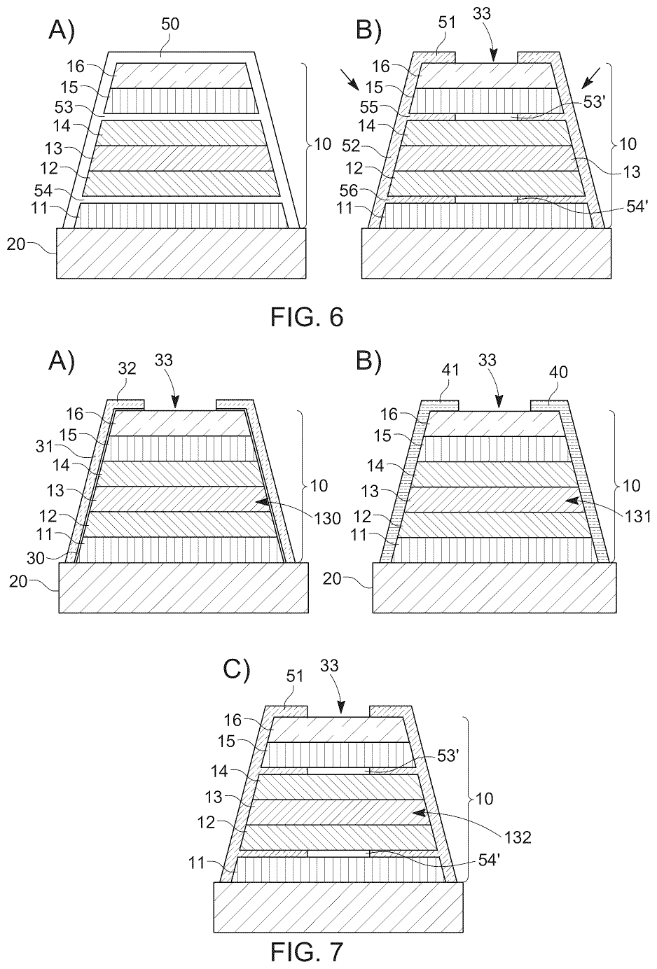

In a subsequent step illustrated in FIG. 6A, an aluminum gallium arsenide layer with an aluminum content of larger than 90% and corresponding to the ones of layer 53 and 54 is deposited. Then, the layer stack is rearranged and exposed to an oxygen containing atmosphere, initiating an oxidation of the aluminum within the layer 50 to provide a sidewall oxidized layer 53 and the top oxidized layer 51, respectively. Due to the oxygen containing atmosphere and the high Al content of layers 53 and 54, a portion of the thin layers 53 and 54 starting from the sidewalls is also oxidized resulting in oxidized thin layer portions 56 and 55.

The oxidation results not only in a defined state of non-radiative recombination centres but also constrain the current carrying layer 53 and 54 to some smaller central portion thereof similar to apertures for the charge carriers, as indicated in FIG. 6B) Hence, the charge density within the active region inside the central portion is significantly increased by the aperture like structure 53′ and 54′, while at the same time a defined amount of non-radiative recombination centres are formed beneath and above the active layer 13 as well as on the circumferential perimeter.

In the previous embodiments, the active layer was not specifically prepared to further improve the fall or rise time by artificially inducing dopants or other structures within the active layer. However, as previously indicated the rise and fall time can be decreased by changing the charge carrier density within the active layer or increasing the non-radiative recombination at the cost of the radiative recombination.

The method according to the proposed principle follows the latter approach but can be combined with other measures to increase the charge density or the bandgap structure to provide a faster radiative recombination. FIG. 7A) to 7C) illustrate respective embodiments thereof. As illustrated in FIG. 7A, the active region 13 comprises a multi-quantum well structure with an additional doping of the quantum well layers 130 to increase of the charge carrier density therein. Consequently, the charge carrier density is increased within the central region of the active layer 13, while the perimeter contains a functional structure 30 providing an increased density of non-radiative recombination centres.

FIG. 7B illustrates a similar embodiment with a multi-quantum well structure implemented as active layer 13. In this particular embodiment, a doping is introduced into the barrier layers 131 of the multi-quantum well structure, thereby also increasing the charge carrier density therein. A dielectric layer 40 providing a charged interface states on the perimeter of the active layer 13 is deposited on the inclined sidewalls.

A further embodiment illustrated in FIG. 7C shows that the active layer 13 comprises a plurality of quantum dots 132 made of aluminum gallium arsenide and gallium arsenide instead of a quantum well structure. The quantum dots comprise a reduced recombination time, thereby allowing a higher switchability of such optoelectronic device. In addition, the density of the quantum dots within the active layer can be varied and adjusted with a focus on the central region. In this embodiment an oxide aluminum gallium arsenide layer was introduced on the sidewalls and oxidized together with an aperture as in the previous embodiments.

In those embodiments, it is noted that measures for processing the sidewall and mesa facets to introduce a defined state on non-radiative recombination centres at the perimeter of active layer 13 can be combined with measures within the active layer to increase the charge carrier density in the central portion.

1.-18. (canceled)

19. An optoelectronic device comprising:
a semiconductor layer stack comprising a first doped layer comprising a first doping type, a second doped layer comprising a second doping type and an active layer between the first doped layer and the second doped layer,
wherein a material of the semiconductor layer stack comprises AlGaAs and/or GaAs,
wherein the semiconductor layer stack comprises mesa sidewalls extending from the first doped layer to the second doped layer; and
a functional structure arranged on a surface of the sidewalls at least at the active layer, the functional structure configured to cause a reduction of a radiative recombination lifetime, wherein the functional structure comprises a dielectric oxide containing layer disposed on the sidewalls of the semiconductor layer stack and optionally extending partially onto a top surface of the semiconductor layer stack,
a plurality of interface states on the sidewalls at least at the active layer based on a deposition of the dielectric layer,
wherein the functional structure comprises a regrown and oxidized AlₓGa₁₋ₓAs layer disposed on the sidewalls of the semiconductor layer stack and optionally extending partially onto the top surface of the semiconductor layer stack, and
wherein, optionally, x>0.5.

20. The device according to claim 19, wherein the functional structure comprises at least one of:
a roughened surface by a controlled plasma etching process;
an oxidation layer on the surface of the sidewalls at least at the active layer;
a layer configured to terminate dangling bonds of the surface of the sidewalls at least at the active layer;
a functional layer containing one of nitrogen, oxygen, or carbon;
carbon, and/or nitrogen and/or oxygen atoms or molecules configured to saturate dangling bonds of the semiconductor material at the surface; or
an oxide-containing layer arranged on mesa-etched facets.

21. The device according to claim 19, wherein the functional structure is configured to cause a band bending of a band structure of the active layer close to the surface, optionally with a plurality of non-radiative recombination centres located within a band gap of the active layer.

22. The device according to claim 19, wherein the functional structure further comprises a functional layer on the surface of the sidewalls at least at the active layer and an epitaxially regrown encapsulation layer disposed on the functional layer, and wherein the encapsulation layer extends along the sidewalls of the semiconductor layer stack and optionally partially onto the top surface of the semiconductor layer stack.

23. The device according to claim 19, wherein the dielectric oxide containing layer comprises at least one of SiO2, Nb2O5, HfO2, SiN or SiON.

24. The device according to claim 19,
wherein the layer stack comprises a partially oxidized AlₓGa₁₋ₓAs layer arranged between the first doped layer and the active layer and/or the second doped layer and the active layer,
wherein x>0.5,
wherein, optionally, the partially oxidized AlₓGa₁₋ₓAs layer comprises a thickness in a range of 5 nm to 20 nm, and/or
wherein, optionally, the partially oxidized AlₓGa₁₋ₓAs layer is doped, and/or
wherein, optionally, an oxidized portion of the partially oxidized AlₓGa₁₋ₓAs layer ranges from about 10 % to about 60% of an overall area of the AlₓGa₁₋ₓAs layer.

25. The device according to claim 19, wherein the semiconductor layer stack comprises a first cladding layer and a second cladding layer directly adjacent to the active layer.

26. The device according to claim 19, wherein the active layer comprises at least one of:
at least one quantum well layer comprising a doping level in a range between 1e16 1/cm³ and 1e18 2/cm³, inclusive,
at least two barrier layers encompassing at least one quantum well layer, the at least two barrier layers comprising a doping level in a range between 1e16 1/cm³ and 1e18 1/cm³, inclusive, or
a plurality of quantum dots.

27. The device according to claim 19, wherein the device is an optical data communication device.

28. A method for processing an optoelectronic device, the method comprising:
providing a semiconductor layer stack comprising a first doped layer comprising a first doping type, a second doped layer comprising a second doping type and an active layer between the first and second doped layer, wherein a material of the semiconductor layer stack comprises AlGaAs and/or GaAs;
mesa etching the semiconductor layer stack to form inclined sidewalls extending from the first doped layer to the second doped layer;
cleaning and optionally annealing the mesa-etched sidewalls;
generating a functional structure on a surface of the cleaned mesa-etched sidewalls at least at the active layer causing a reduction of a radiative recombination lifetime,
wherein generating the functional structure comprises:
regrowing an AlₓGa₁₋ₓAs layer on the mesa-etched sidewalls of the semiconductor layer stack and optionally extending partially onto a top surface of the semiconductor layer stack, wherein x>0.5, and
oxidizing the regrown AlₓGa₁₋ₓAs layer, and
wherein during the deposition of the oxidized regrown AlₓGa₁₋ₓAs layer a plurality of interface states is formed on the mesa-etched sidewalls at least at the active layer.

29. The method according to claim 28, wherein the functional structure causes a band bending of the band structure of the active layer close to a surface, optionally with a plurality of non-radiative recombination centers located with respective energy states within a band gap of the active layer.

30. The method according to claim 28, wherein the functional structure causes a plurality of non-radiative recombination centers located with respective energy states within a band gap of the active layer.

31. The method according to claim 28, wherein generating the functional structure comprises at least one of:
roughening the cleaned surface by a controlled plasma etching process, and, optionally, adding one of nitrogen, oxygen, or carbon during the etching process;
depositing an oxygen containing layer on the cleaned surface; or
depositing a layer onto mesa facets terminating dangling bonds of the surface of the mesa-etched sidewalls at least at the active layer.

32. The method according to claim 28, wherein generating the functional structure further comprises depositing an encapsulation layer on a functional layer, and wherein the encapsulation layer extends along the mesa-etched sidewalls of the semiconductor layer stack and optionally partially onto the top surface of the semiconductor layer stack.

33. The method according to claim 28, wherein the functional structure further comprises a dielectric oxide containing layer comprising at least one of SiO2, Nb2O5, HfO2, SiN or SiON.

34. The method according to claim 28, wherein providing the semiconductor layer stack comprises:
depositing an AlₓGa₁₋ₓAs layer between the first doped layer and the active layer and/or the second doped layer and the active layer, wherein x>0.5,
wherein, optionally, the AlₓGa₁₋ₓAs layer comprises a thickness in a range of 5 nm to 20 nm, inclusive, and/or
wherein, optionally, the AlₓGa₁₋ₓAs layer is doped.

35. The method according to claim 28, wherein the semiconductor layer stack comprises a first cladding layer and a second cladding layer directly adjacent to the active layer.
